(19) United States
(12) Patent Application Publication
(10) Pub. No.: US 2017/0110427 A1
(43) Pub. Date: Apr. 20, 2017

(54) CHIP PACKAGE AND METHOD FOR MANUFACTURING SAME

(71) Applicants: FuKui Precision Component (Shenzhen) Co., Ltd., Shenzhen (CN); HongQiSheng Precision Electronics (QinHuangDao) Co., Ltd., Qinhuangdao (CN); Zhen Ding Technology Co., Ltd., Tayuan (TW)

(72) Inventor: WEI-SHUO SU, New Taipei (TW)

(21) Appl. No.: 14/966,946

(22) Filed: Dec. 11, 2015

(30) Foreign Application Priority Data
Oct. 19, 2015 (CN) 201510682734.7

(51) Int. Cl. H01L 23/00; H01L 21/56; H01L 21/48; H01L 23/31; H01L 23/498

(52) U.S. Cl. CPC H01L 24/13; H01L 24/02; H01L 23/3114; H01L 23/49827; H01L 23/49816; H01L 23/49838; H01L 21/4853; H01L 21/486; H01L 21/565; H01L 21/568; H01L 2224/02372; H01L 2224/02379; H01L 2224/13014; H01L 2224/13024; H01L 2924/014

(57) ABSTRACT

A chip package can include a chip, a plurality of metal posts, an encapsulating body and a redistribution layer. The plurality of metal posts surrounds the chip. The encapsulating body surrounds the chip and the plurality of metal posts. The redistribution layer is coupled to the encapsulating body and electrically coupled to the chip and the plurality of metal posts. A method for manufacturing the chip package is also provided.

### FIELD

The subject matter herein generally relates to chip packages, and particularly to a chip package and a method for manufacturing the chip package.

### BACKGROUND

A chip package generally includes an encapsulating body enclosing or installing a semiconductor chip. The encapsulating body not only has functions of positioning, fixing, sealing, protection, enhancing thermal conductivity or others, but also has a function of acting as a bridge between the chip and an external circuit out of the encapsulating body. Generally, the chip is electrically coupled to a wire out of the encapsulating body via a wire or other conductors coupled to two junctions of the chip. The wire is further electrically coupled to other components via a printed circuit board.

### BRIEF DESCRIPTION OF THE DRAWINGS

Implementations of the present technology will now be described, by way of example only, with reference to the attached figures.

FIG. 1 is a cross sectional view of a chip package in accordance with a first embodiment of the present disclosure.

FIG. 2 is a flow chart of a method for manufacturing the chip package in FIG. 1.

FIG. 3 is a cross sectional view of a supporting substrate.

FIG. 4 is a cross sectional view of the supporting substrate in FIG. 3 with a plurality of metal posts.

FIG. 5 is a cross sectional view of a structure in FIG. 4 with a chip soldered to the supporting substrate.

FIG. 6 is a cross sectional view of the plurality of metal posts and the chip in FIG. 5 surrounded by an encapsulating body.

FIG. 7 shows the encapsulating body in FIG. 6 being polished.

FIG. 8 shows the supporting substrate in FIG. 7 being removed to form a package substrate.

FIG. 9 is a cross sectional view of the package substrate in FIG. 8 with a redistribution layer coupled to a side of the package substrate.

FIG. 10 is a cross sectional view of a chip package in accordance with a second embodiment of the present disclosure.

FIG. 11 shows a plurality of conductive holes formed and corresponding to the plurality of metal posts in FIG. 5.

FIG. 12 is a cross sectional view of a structure in FIG. 11 with the supporting substrate being removed.

FIG. 13 shows a redistribution layer being formed to the structure in FIG. 12.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to a chip package. The chip package can include a chip, a plurality of metal posts, an encapsulating body and a redistribution layer. The plurality of metal posts surrounds the chip. The encapsulating body surrounds the chip and the plurality of metal posts. The redistribution layer is coupled to the encapsulating body and electrically coupled to the chip and the plurality of metal posts.

The present disclosure is described further in relation to a method for manufacturing a chip package. The method can include the following components. A supporting substrate is provided. A plurality of metal posts are formed on the supporting substrate. A chip is mounted on the supporting substrate. The chip is surrounded by the plurality of metal posts. An encapsulating body surrounds the plurality of metal posts and the chip. The supporting substrate is removed to form a package substrate. A redistribution layer is formed at a side of the package substrate. The redistribution layer is electrically coupled to the plurality of metal posts and the chip.

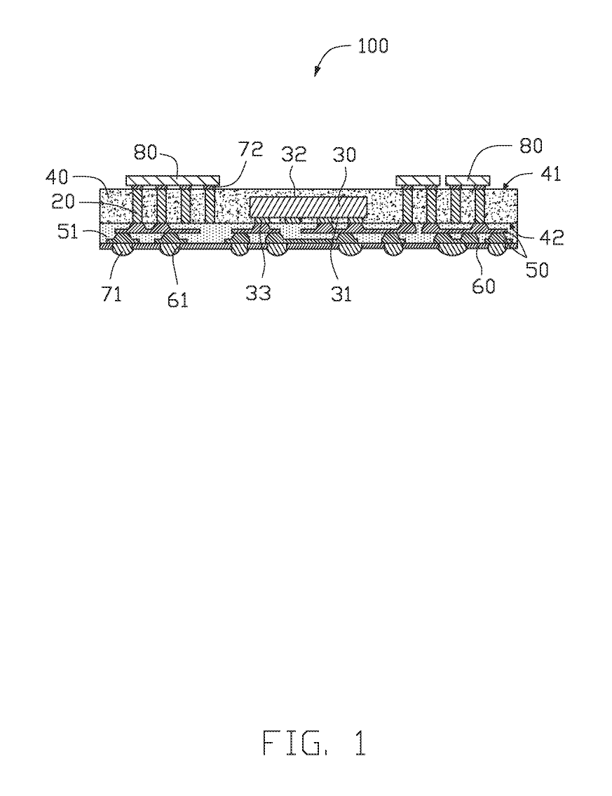

FIG. 1 illustrates a chip package 100 of a first embodiment of the present disclosure. The chip package 100 can be a system in package (SIP). The chip package 100 can include a plurality of metal posts 20, a chip 30 surrounded by the plurality of metal posts 20, an encapsulating body 40 surrounding the plurality of metal posts 20 and the chip 30, a redistribution layer 50 electrically coupled to the plurality of metal posts 20 and the chip 30, an insulating layer 51 surrounding the redistribution layer 50, a solder resist layer 60 coupled to the redistribution layer 50, and a plurality of external electronic components 80 electrically coupled to the plurality of metal posts 20.

Each of the plurality of metal posts 20 can be a copper post or other metal post. The plurality of metal posts 20 are configured to be electrical connection channels between the redistribution layer 50 and the external electronic components 80, and support the encapsulating body 40, to avoid warping of the encapsulating body 40.

Each of the plurality of metal posts 20 can have, but not limited to a circular section. The section of each of the plurality of metal posts 20 also can be rectangular, triangular, elliptic or other figurates. Each of the plurality of metal posts 20 has a first end face and a second end face opposite to the first end face.

The chip 30 is surrounded by the meal posts 20. In at least one embodiment, the chip package 100 can include one chip 30. The chip 30 can include a first surface 31 and a second surface 32 opposite to the first surface 31. The first surface 31 has a plurality of electrically conductive blocks 33 coupled thereto. In at last one embodiment, each of the electrically conductive blocks 33 has an end face coplanar with the first end faces of the plurality of metal posts 20.

The encapsulating body 40 surrounds the plurality of metal posts 20 and the chip 30. The encapsulating body 40 exposes the first end faces and the second end faces of the plurality of metal posts 20 to the redistribution layer 50 and the external electronic components 80, respectively. The encapsulating body 40 exposes the end faces of the electrically conductive blocks 33 to the redistribution layer 50. The encapsulating body 40 can include a first face 41 and a second face 42 opposite and parallel to the first face 41. In at least one embodiment, the first face 41 and the second face 42 are parallel to the first surface 31 and the second surface 32 of the chip 30. The first face 41 is flush with the second end faces of the plurality of metal posts 20. The second face 42 is flush with the first end faces of the plurality of metal posts 20 and the end faces of the electrically conductive blocks 33.

The redistribution layer 50 is coupled to the second face 42 of the encapsulating body 40 and is electrically coupled to some of the plurality of metal posts 20 and the electrically conductive blocks 33.

The insulating layer 51 surrounds the redistribution layer 50 to protect the redistribution layer 50. The insulating layer 51 can have a first face coupled to the second face 42 of the encapsulating body 40 and a second face remote from the second face 42. The second face of the insulating layer 51 is flush with a face of the redistribution layer 50 remote from the second face 42.

The solder resist layer 60 is coupled to the second face of the insulating layer 51 and the face of the redistribution layer 50 remote from the second face 42 of the encapsulating body 40. The solder resist layer 60 defines a plurality of through holes 61.

A plurality of first solder balls 71 are coupled in the through holes 61 to be electrically coupled to the redistribution layer 50, for electrically coupling external electronic devices to the redistribution layer 50.

A plurality of second solder balls 72 are coupled to the second end faces the plurality of metal posts 20 remote from the redistribution layer 50.

The external electronic components 80 are electrically coupled to the second solder balls 72.

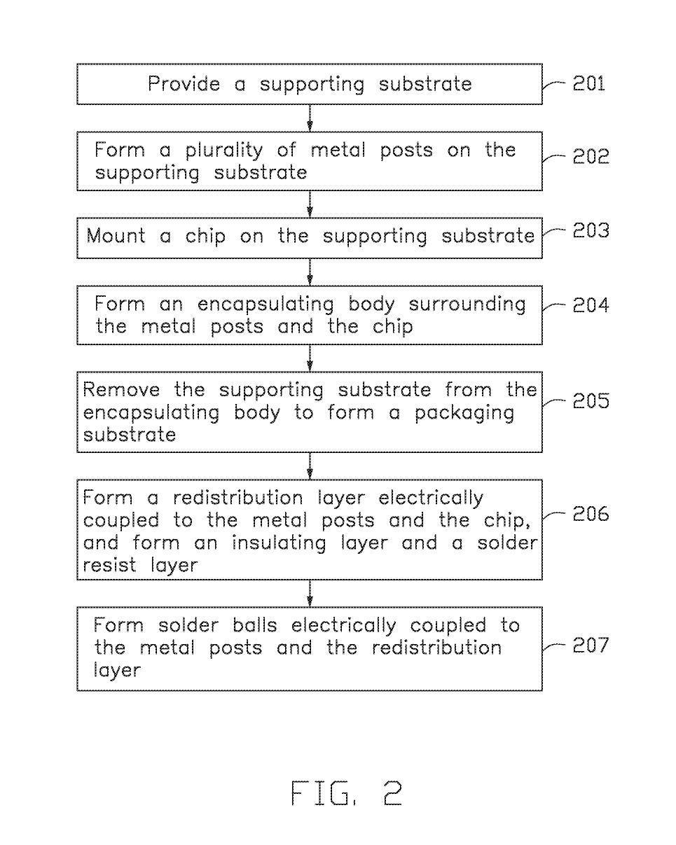

FIG. 2 illustrates a flowchart of an example method for manufacturing the chip package 100. The example method is provided by way of example, as there are a variety of ways to carry out the method. The example method described below can be carried out using the configurations illustrated in FIGS. 1 and 3-9, for example, and various elements of these figures are referenced in explaining the example method. Each block shown in FIG. 2 represents one or more processes, methods or subroutines, carried out in the example method. Furthermore, the illustrated order of blocks is illustrative only and the order of the blocks can change according to the present disclosure. Additional blocks can be added or fewer blocks may be utilized, without departing from this disclosure. The example method can begin at block 201.

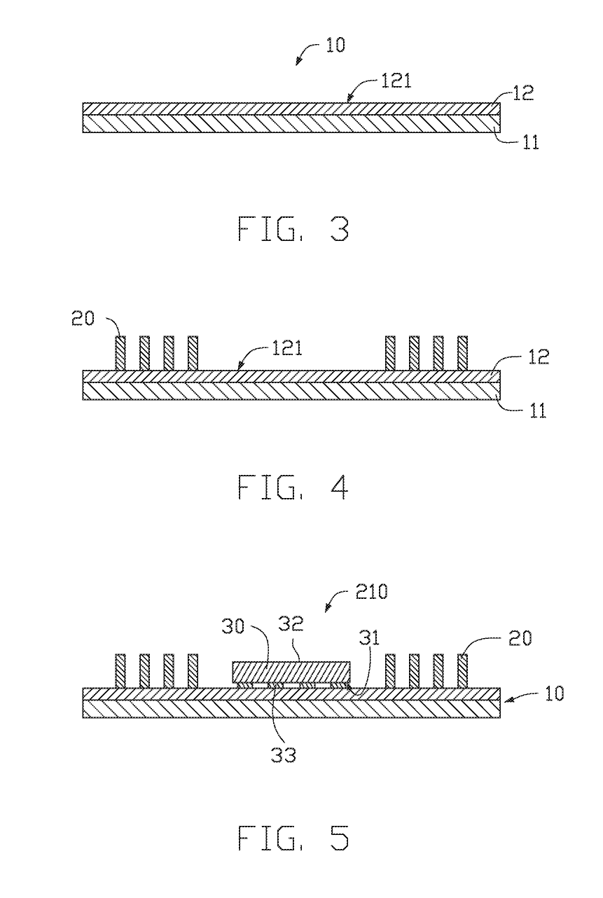

At block 201, referring to FIG. 3, a supporting substrate 10 is provided, the supporting substrate 10 can include a supporting base 11 and a crystal seed layer 12 coupled on the supporting base 11.

The supporting base 11 can be an insulating support plate. In at least one embodiment, a material of the supporting base 11 is polyimide (PI). In at least one alternative embodiment, a material of the supporting base 11 can be polyethylene terephthalate (PET), polyethylene naphthalate (PEN) or other hard resin materials.

The crystal seed layer 12 can be a chemical copper plating layer, or a primary copper layer. The crystal seed layer 12 includes a first surface 121 remote from the supporting base 11 and a second surface opposite to the first surface 121 and coupled to the supporting base 11.

At block 202, also referring to FIG. 4, a plurality of metal posts 20 are formed on the first surface 121 of the crystal seed layer 12.

The plurality of metal posts 20 can be formed by image transfer process and electroplating process. In at least one alternative embodiment, the plurality of metal posts 20 can be directly formed by electroplating process.

Each of the plurality of metal posts 20 can be a copper post or other metal post. Each of the plurality of metal posts 20 can have, but not limited to a circular section. The section of each of the plurality of metal posts 20 also can be rectangular, triangular, elliptic or other figurate. Each of the plurality of metal posts 20 has a first end face coupled to the first surface 121 of the crystal seed layer 12 and a second end face opposite to the first end face and remote from the first surface 121.

At block 203, referring to FIG. 5, a chip 30 is provided and mounted on the first surface 121 of the crystal seed layer 12, to form a package intermediate 210.

In the illustrated embodiment, the chip 30 has a height less than a height of each of the plurality of metal posts 20. The chip 30 is surrounded by the plurality of metal posts 20. The chip 30 has a first surface 31 and a second surface 32 opposite to the first surface 31. The first surface 31 facing the first surface 121 of the crystal seed layer 12. The first surface 31 has a plurality of electrically conductive blocks 33 coupled to the first surface 121 of the crystal seed layer 12. In at last one embodiment, each of the electrically conductive blocks 33 has an end face coplanar with the first end faces of the plurality of metal posts 20.

At block 204, also referring to FIG. 6, an encapsulating body 40 is formed on the first surface 121 of the crystal seed layer 12 to surround the plurality of metal posts 20 and the chip 30.

The encapsulating body 40 includes a first face 41 and a second face 42 opposite to the first face 41. The first face 41 extends beyond the second surface 32 of the chip 30 and the second end faces of the plurality of metal posts 20 remote from the first surface 121, along a direction perpendicular and remote from the first surface 121. The second face 42 is coupled to the first surface 121. In at least one embodiment, the second face 42 is in direct contact with the first surface 121.

In the illustrated embodiment, the encapsulating body 40 can be made by a method of injection molding. The method can include the following components. A mould is provided. The mould includes a cavity and a resin injection channel. The supporting substrate 10 with the plurality of metal posts 20 and the chip 30 is received in the cavity. The resin is injected into the cavity via the resin injection channel to be filled in gaps between the plurality of metal posts 20 and the chip 30, and surrounding the plurality of metal posts 20 and the chip 30. The resin in the cavity is cured to form the encapsulating body 40. The encapsulating body 40 with the supporting substrate 10, the plurality of metal posts 20, and the chip 30 is taken out from the cavity.

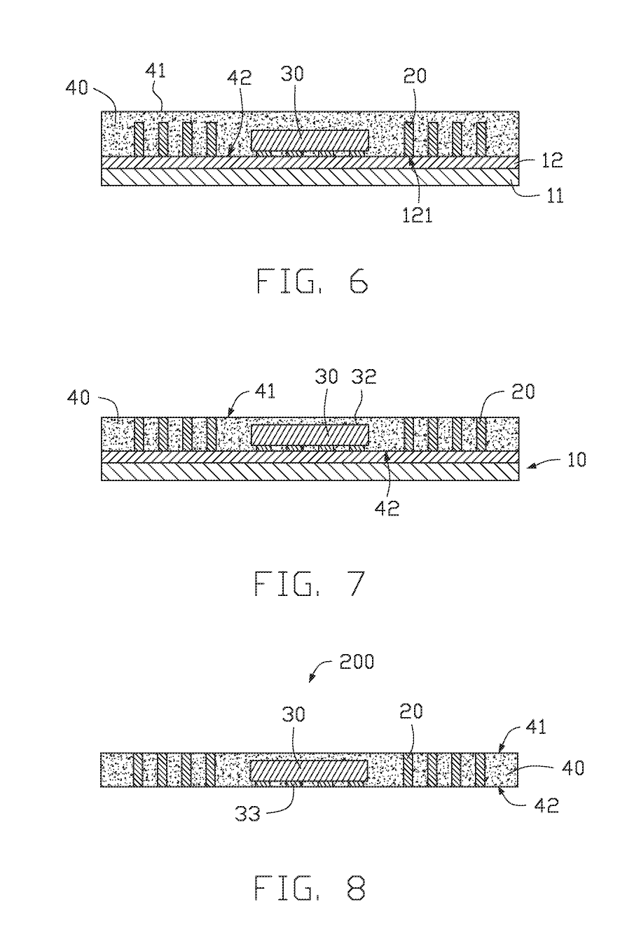

At block 205, also referring to FIG. 7 and FIG. 8, the supporting substrate 10 is removed from the encapsulating body 40 to form a packaging substrate 200.

Referring to FIG. 7, a portion of the encapsulating body 40 remote from the first surface 121 of the crystal seed layer 12 is polished to have the first face 41 of the encapsulating body 40 flush with and exposing the second end faces of the plurality of metal posts 20. Then, referring FIG. 8, the supporting substrate 10 is removed from the second face 42 of the encapsulating body 40. The second face 42 is flush with and exposes the first end faces of the plurality of metal posts 20 and the end faces of the electrically conductive blocks 33.

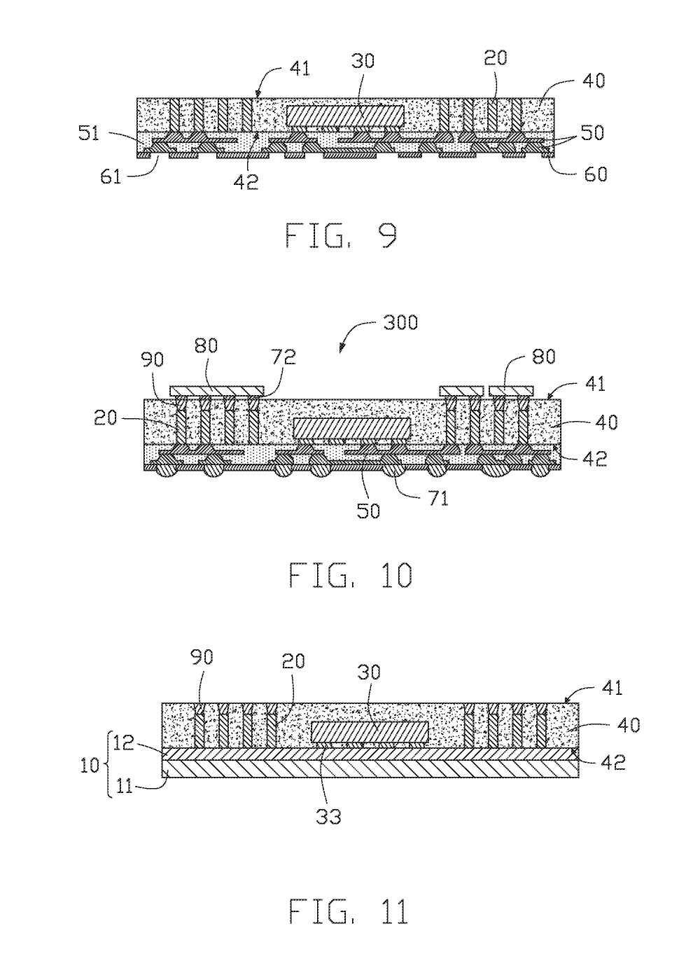

At block 206, also referring to FIG. 9, a redistribution layer (RDL) 50 is formed at a side of the packaging substrate 200, an insulating layer 51 is formed to surround the redistribution layer 50, and a solder resist layer 60 is formed on a face of the redistribution layer 50 remote from the packaging substrate 20.

The redistribution layer 50 is formed basing on the packaging substrate 200, and allows components to be installed and to communicate with each other, or to communicate with external electronic components. In at least one embodiment, the redistribution layer 50 is formed by electroplating process.

The redistribution layer 50 electrically coupled to some of the plurality of metal posts 20 and the electrically conductive blocks 33.

The insulating layer 51 surrounds the redistribution layer 50 to protect the redistribution layer 50. The insulating layer 51 can have a first face coupled to the second face 42 of the encapsulating body 40 and a second face remote from the second face 42. The second face of the insulating layer 51 is flush with a face of the redistribution layer 50 remote from the second face 42.

The solder resist layer 60 is formed on the second face of the insulating layer 51 and the face of the redistribution layer 50 remote from the second face 42 of the encapsulating body 40. The solder resist layer 60 defines a plurality of through holes 61.

At block 207, also referring to FIG. 1, a plurality of first solder balls 71 are formed in the through holes 61 of the solder resist layer 60, and a plurality of second solder balls 72 are formed on the second end faces of the plurality of metal posts 20, a chip package 100 is obtained.

The plurality of first solder balls 71 are electrically coupled to the redistribution layer 50, for electrically coupling external electronic devices to the redistribution layer 50. In at least one alternative embodiment, the first solder balls 71 can be omitted, here, the redistribution layer 50 can be directly electrically coupled to the external electronic devices.

The plurality of second solder balls 72 are electrically coupled to the second end faces the plurality of metal posts 20 remote from the redistribution layer 50 and external electronic components 80. The external electronic components 80 can be chips, circuit boards or others.

In the illustrated embodiment, the plurality of metal posts 20 are configured to be electrical connection channels between the redistribution layer 50 and the external electronic components 80, and support the encapsulating body 40, to avoid warping of the encapsulating body 40.

FIG. 10 illustrates a chip package 300 of a second embodiment of the present disclosure. The chip package 300 has a configuration similar to that of the chip package 100 of the first embodiment. A difference between the chip package 300 and the chip package 100 is that the chip package 300 further includes a plurality of electrically conductive holes 90 electrically coupled to the plurality of metal posts 20 and the second solder balls 72. Each of the electrically conductive holes 90 can be an electrically conductive blind hole.

The plurality of electrically conductive holes 90 are corresponding to the plurality of metal posts 20 one-to-one. Each of the conductive holes 90 is surrounded by the encapsulating body 40 and concaved from the second face 42 of the encapsulating body 40 to the second end face of a corresponding metal post 20. Each of the plurality of electrically conductive holes 90 has an end surface exposed out of and flush with the second face 42 of the encapsulating body 40. Each of the electrically conductive holes 90 is electrically coupled between the second end face of the corresponding metal post 20 and a corresponding second solder ball 72.

Referring to FIGS. 10-13, a method for manufacturing the chip package 300 is similar to the method for manufacturing the chip package 100. A different between the method for manufacturing the chip package 300 and the method for manufacturing the chip package 100 is that the method for manufacturing the chip package 300 including the following components.

FIG. 11 illustrates that, before the supporting substrate 10 is removed from the second face 42 of the encapsulating body 40, a plurality of electrically conductive holes 90 are formed corresponding to the plurality of metal posts 20 one-to-one. Each of the electrically conductive holes 90 is electrically coupled to a corresponding metal post 20. Each of the electrically conductive holes 90 has an end surface exposed out of and flush with the second face 42 of the encapsulating body 40. The plurality of electrically conductive holes 90 can be formed by laser drilling and electroplating process.

FIG. 12 illustrates that the supporting substrate 10 is removed from the second face 42 of the encapsulating body 40.

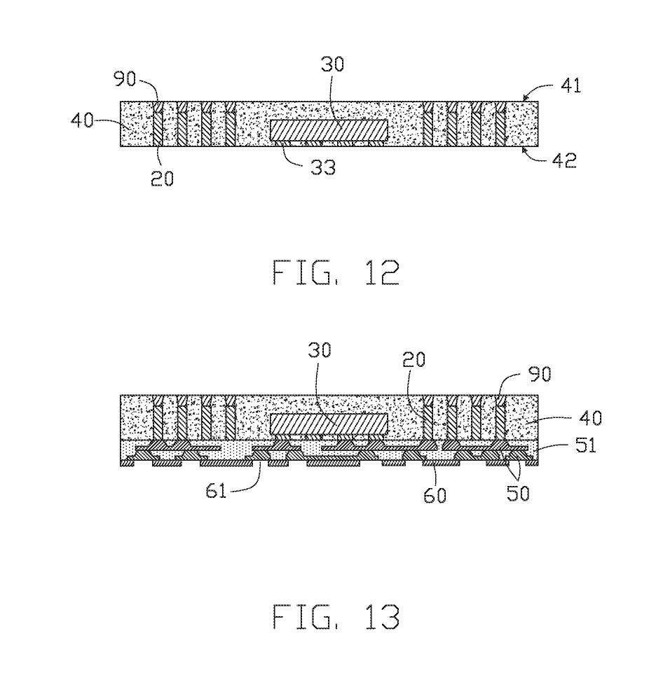

FIG. 13 illustrates that a redistribution layer (RDL) 50 is formed on the second face 42 of the encapsulating body 40, an insulating layer 51 is formed to surround the redistribution layer 50, and a solder resist layer 60 is formed on a face of the redistribution layer 50 remote from the second face 42 of the encapsulating body 40. The solder resist layer 60 defines a plurality of through holes 61.

FIG. 10 illustrates that a plurality of first solder balls 71 are formed in the through holes 61 of the solder resist layer 60, and a plurality of second solder balls 72 are formed on the end surfaces of the conductive holes 90 and electrically coupled to a plurality of external electronic components 80, a chip package 300 is obtained.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A chip package comprising:
a chip;
a plurality of metal posts surrounding the chip;
an encapsulating body surrounding the chip and the plurality of metal posts; and
a redistribution layer coupled to the encapsulating body and electrically coupled to the chip and the plurality of metal posts.

2. The chip package of claim 1, wherein the encapsulating body comprises a first face and a second face opposite to the first face, the redistribution layer is coupled to the second face, each of the plurality of metal posts having a first end thereof exposed to the redistribution layer at the second face, and a second end opposite to the first end.

3. The chip package of claim 2, wherein the second end is exposed at the first face of the encapsulating body.

4. The chip package of claim 3, wherein the second end of each of the plurality of metal posts is flush with the first face of the encapsulating body.

5. The chip package of claim 3, wherein the second end of each of the plurality of metal posts is electrically coupled to a solder ball.

6. The chip package of claim 2, further comprising a plurality of electrically conductive holes, wherein the second end of each of the plurality of metal posts is electrically coupled to a corresponding one of the electrically conductive holes.

7. The chip package of claim 6, wherein the encapsulating body surrounds each of the electrically conductive holes.

8. The chip package of claim 7, wherein each of the electrically conductive holes has an end surface flush with the first face of the encapsulating body and coupled to a solder ball.

9. The chip package of claim 2, wherein the chip has a plurality of electrically conductive blocks coupled to the redistribution layer.

10. The chip package of claim 9, wherein each of the electrically conductive blocks is exposed to the redistribution layer at the second face.

11. The chip package of claim 2, further comprising an insulating layer, wherein the insulating layer is coupled to the second face of the encapsulating body and surrounds the redistribution layer, the redistribution layer having a face exposing the insulating layer.

12. The chip package of claim 11, further comprising a solder resist layer coupled to the face of the redistribution layer, wherein the solder resist layer defines a plurality of through holes each receiving a solder ball, the solder ball electrically coupled to the redistribution layer.

13. A method for manufacturing a chip package, comprising:
providing a supporting substrate;
forming a plurality of metal posts on the supporting substrate, and mounting a chip on the supporting substrate, the chip being surrounded by the plurality of metal posts;
forming an encapsulating body surrounding the plurality of metal posts and the chip;
removing the supporting substrate to form a package substrate; and
forming a redistribution layer at a side of the package substrate, the redistribution layer electrically coupled to the plurality of metal posts and the chip.

14. The method of claim 13, wherein the chip forms a plurality of electrically conductive blocks electrically coupled to the redistribution layer.

15. The method of claim 13, wherein the encapsulating body comprises a first face and a second face opposite to the first face, the redistribution layer is coupled to the second face, each of the plurality of metal posts having a first end thereof exposed to the redistribution layer at the second face, and a second end opposite to the first end.

16. The method of claim 15, before removing the supporting substrate, further comprising:
polishing the encapsulating body from the second face toward the plurality of metal posts to expose the second ends of the plurality of metal posts.

17. The method of claim 15, before removing the supporting substrate, further comprising:
forming a plurality of electrically conductive holes correspondingly electrically coupled to the second ends of the plurality of metal posts, wherein each of the electrically conductive holes is surrounded by the encapsulating body and has an end surface expose out of the encapsulating body at the second face.

18. The method of claim 15, after forming the redistribution layer, further comprising:
forming an insulating layer surrounding the redistribution layer, and forming a solder resist layer on a face of the redistribution layer remote from the encapsulating body.

19. The method of claim 18, wherein the solder resist layer defines a plurality of through holes, a plurality of solder balls being formed in the through holes to be electrically coupled to the redistribution layer.

20. The method of claim 19, further comprising:
forming a plurality of solder balls electrically coupled to the second ends of the plurality of metal posts.
